(19) United States
(12) Patent Application Publication
(10) Pub. No.: US 2024/0290880 A1
(43) Pub. Date: Aug. 29, 2024

(54) METHOD FOR PRODUCING A VERTICAL FIELD-EFFECT TRANSISTOR STRUCTURE AND CORRESPONDING VERTICAL FIELD-EFFECT TRANSISTOR STRUCTURE

(71) Applicant: Robert Bosch GmbH, Stuttgart (DE)

(72) Inventors: Daniel Krebs, Aufhausen (DE); Kevin Dannecker, Reutlingen (DE)

(21) Appl. No.: 18/441,170

(22) Filed: Feb. 14, 2024

(30) Foreign Application Priority Data
Feb. 24, 2023 (DE) 10 2023 201 683.4

(51) Int. Cl. H01L 29/78; H01L 29/06; H01L 29/417; H01L 29/66

(52) U.S. Cl. CPC H01L 29/7813; H01L 29/0619; H01L 29/0634; H01L 29/41791; H01L 29/66734; H01L 29/66795; H01L 29/785

(57) ABSTRACT

A vertical field-effect transistor structure, and a method for producing the structure. The structure includes a semiconductor body having a first terminal zone, a drift zone, and a second terminal zone of a first conductivity type; a channel zone, between the first and the second terminal zone, of the first or second conductivity type; first trenches extending into the semiconductor body, which extend from the second terminal zone into the drift zone and form fins of the channel and second terminal zones; a control electrode arranged in the first trenches, adjacent to the channel zone and insulated from the semiconductor body; and a current path connected between the first and the second terminal zone and in parallel with the channel zone, the current path having at least one Schottky junction and which conducts when a reverse voltage between the first and the second terminal zones is reached.

### CROSS REFERENCE

The present application claims the benefit under 35 U.S.C. § 119 of German Patent Application No. DE 10 2023 201 683.4 filed on Feb. 24, 2023, which is expressly incorporated herein by reference in its entirety.

### FIELD

The present invention relates to a method for producing a vertical field-effect transistor structure and to a corresponding vertical field-effect transistor structure.

### BACKGROUND INFORMATION

Power MOSFETs with a vertical channel region (TMOSFETs) are typically used for the application of semiconductors with a wide band gap (e.g., silicon carbide (SiC) or gallium nitride (GaN)) in power electronics.

In the TMOSFET design, the n+ source region situated in a semiconductor material and the p channel region are interrupted by trenches that extend up to the n− drift region. Inside the trenches there is a gate electrode, which is separated from the semiconductor material by a gate oxide and is used to control the channel region.

By suitable selection of the geometry, epitaxial doping, channel doping, and screening doping, the switch-on resistance, threshold voltage, short-circuit resistance, oxide load, and breakdown voltage of such TMOSFETs can be optimized.

FIG. 9 shows a sectional view of an exemplary vertical field-effect transistor structure.

The field-effect transistor structure comprises a semiconductor body 100. A source electrode 80 contacts semiconductor fins FI separated by trenches G with a p-doped channel region 20, which fins have for this purpose an n⁺-doped source terminal region 30 in the upper region of the relevant fin FI. Next to the fins FI are arranged gate electrodes 40, which are separated from the fins FI and from the other regions by a gate dielectric 40a.

In the present case of a FinMOS, the p-doped channel regions 20 are introduced within the fins FI and adjacent to the gate electrodes 40, but in the case of a FinFET these regions can also have the same doping type as an n-drift zone 12. In the region below the fins FI there are p⁺-doped shielding regions 90. These are electrically connected by the source electrode 80 via a contact metal region 10. The n⁻-doped drift zone 12, which merges into an n+-doped drain terminal region 14, extends below this. The n⁺-doped region drain terminal region 14 can be for example a substrate wafer, whereas the other regions are formed epitaxially. The n⁺-doped region drain terminal region 14 is electrically contacted via a drain electrode 9. Without applying a voltage to the gate electrodes 40, the corresponding field-effect transistor is not conductive. By applying a gate voltage to the gate electrode 40, a conductive channel is formed in the channel region 20 at the boundary to the gate dielectric 40a.

An important characteristic variable in such power transistors is the short-circuit strength. This describes how long or how well a component can withstand a short circuit, i.e., the full system voltage at the connected transistor, and how quickly it can then switch off. When switching off, it is important that the space charge region under the fins FI forms quickly in the area between the p⁺-doped shielding regions 90 in order to thus shield the gate complex.

However, a space charge zone based on a pn junction reacts relatively slowly due to the minority charge carriers present.

The present invention provides ways in which such a Schottky junction can help to improve the short-circuit strength and the switching behavior of the transistor in general.

### SUMMARY

The present invention provides a vertical field-effect transistor structure and a method for producing a vertical field-effect transistor structure.

Preferred example embodiments and developments of the present invention are disclosed herein.

An underlying idea of the present invention is to improve the short-circuit strength and generally the switching behavior of the transistor by means of a Schottky junction.

By inserting a Schottky contact at the base of the fins, the complex and expensive p⁺-doping of the shielding elements can be dispensed with. By suitably arranging the Schottky contact, the region under the fins can be depleted more quickly. This in turn is decisive for the short-circuit strength and the switching behavior.

According to a preferred development of the present invention, a terminal contact is provided on the highly conductive region and a contact metallization extends into the first trenches, which electrically connects the terminal contact and the second terminal zone. This enables a simple electrical connection of the Schottky junction.

According to a further preferred development of the present invention, the highly conductive region extends up to below the control electrode. This increases the shielding effect.

According to a further preferred development of the present invention, in the drift zone between the highly conductive region and the first terminal zone there is arranged a region of the second conductivity type which electrically connects the highly conductive region to the first terminal zone. An effective superjunction region can thus be formed.

According to a further preferred development of the present invention, the drift region is formed from silicon carbide and the highly conductive region is formed from polysilicon.

According to a further preferred development of the present invention, a superjunction region of the second conductivity type, which electrically connects the highly conductive region to the first terminal zone, is arranged in the drift zone between the highly conductive region and the first terminal zone.

### BRIEF DESCRIPTION OF THE DRAWINGS

Further features and advantages of the present invention are explained below with the aid of embodiments, with reference to the figures.

FIGS. 1A-1F are schematic partial cross-sectional views for explaining a method for producing a vertical field-effect transistor structure and a corresponding vertical field-effect transistor structure according to a first embodiment of the present invention.

FIG. 2 is a schematic partial cross-sectional view for explaining a vertical field-effect transistor structure according to a second embodiment of the present invention.

FIG. 3 is a schematic partial cross-sectional view for explaining a vertical field-effect transistor structure according to a third embodiment of the present invention.

FIG. 4 is a schematic partial cross-sectional view for explaining a vertical field-effect transistor structure according to a fourth embodiment of the present invention.

FIG. 5 is a schematic partial cross-sectional view for explaining a vertical field-effect transistor structure according to a fifth embodiment of the present invention.

FIG. 6 is a schematic partial cross-sectional view for explaining a vertical field-effect transistor structure according to a sixth embodiment of the present invention.

FIG. 7 is a schematic partial cross-sectional view for explaining a vertical field-effect transistor structure according to a seventh embodiment of the present invention.

FIG. 8 is a schematic partial cross-sectional view for explaining a vertical field-effect transistor structure according to an eighth embodiment of the present invention.

FIG. 9 is a partial sectional view of an exemplary vertical field-effect transistor structure.

### DETAILED DESCRIPTION OF EXAMPLE EMBODIMENTS

In the figures, identical reference signs denote identical or functionally identical elements.

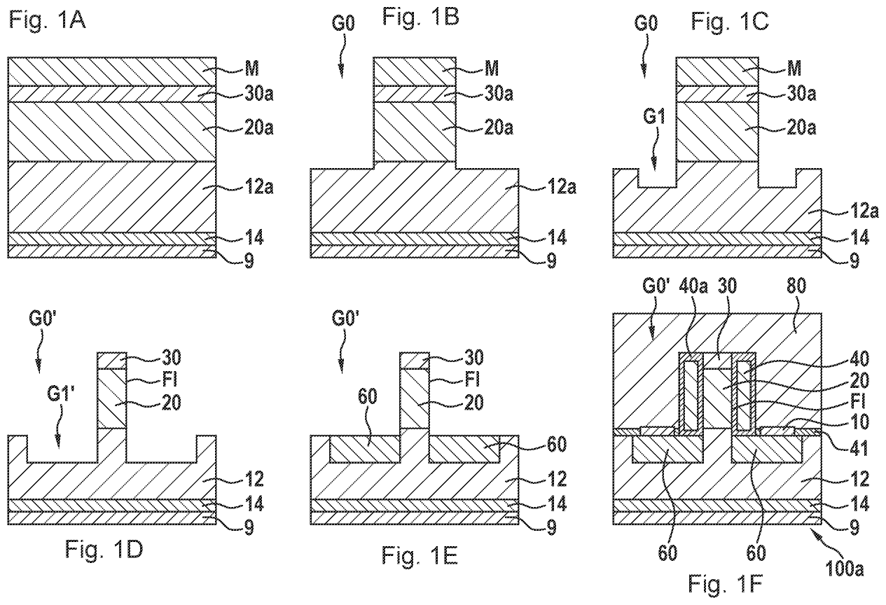

FIGS. 1A-1F are schematic partial cross-sectional views for explaining a method for producing a vertical field-effect transistor structure and a corresponding vertical field-effect transistor structure according to a first embodiment of the present invention.

With reference to FIG. 1A, an n⁺-doped substrate wafer 14, which comprises a metallization 9 on the back, is first provided for the semiconductor body 100a. The substrate wafer 14 forms the drain terminal region in the field-effect transistor structure and the metallization 9 forms the drain contact metallization. An n⁻-doped layer 12a, a p-doped layer 20a, an n⁺-doped layer 30a, and a mask layer M are epitaxially applied on the substrate wafer 14.

Further with reference to FIG. 1B, a mesa etching is carried out to form a precursor structure for the later fins, which is separated by trenches G0.

According to FIG. 1C, further trenches G1 are etched into the n⁻-doped layer 12a to the left and right of the precursor structure of the later fins. The depth of the trenches G1 and their later distance to the fin influences the effectiveness of the shielding and can be selected according to the component requirements.

As shown in FIG. 1D, in a further etching step after removing the mask layer M, the fins FI are formed by narrowing the precursor structure, wherein the trenches G0 and G1 are also widened and thus form first and second trenches G0′ and G1′ of the later vertical field-effect transistor structure.

Subsequently, the second trenches G1′ are each filled with a highly conductive p-region 60, which forms a Schottky junction to the drift region 12 which was formed from the n⁻-doped layer 12a, as shown in FIG. 1E. For silicon carbide as semiconductor material of the drift region 12, CVD polysilicon is for example suitable for forming the Schottky junction.

Finally, with reference to FIG. 1F, in each of the first trenches G0′ a control electrode 40 is formed which is arranged adjacent to the channel zone 20 and insulated from the semiconductor body 100a by a gate dielectric 40a.

On the drift region 12 with the highly conductive regions 60 on both sides of the fin FI, a further dielectric 41 is formed in which a relevant optional connecting contact 10 is provided for the corresponding highly conductive p-regions 60.

Finally, a source contact metallization 80 is provided which contacts the source terminal region 30 and which extends into the first trenches G0′ so that it electrically connects the terminal contact 10 and the source terminal region 30.

In forward operation, the transistor works like an ordinary FinFET or FinMOS. In the blocking case, the Schottky junction between the highly doped region 60 and the drift zone 12 is acted on in the blocking direction and a space charge zone is formed in the drift zone 12. This happens faster than would be the case for a pn junction (cf. FIG. 9). The gate dielectric 40a is thus more effectively protected, which increases the breakdown strength and reliability of the component. The third operating case is reverse operation. Here the Schottky junction is polarized in the forward direction and the current flows via the Schottky junction. The reverse recovery behavior here leads to lower voltage transients and lower overvoltages during commutation than with a pn junction.

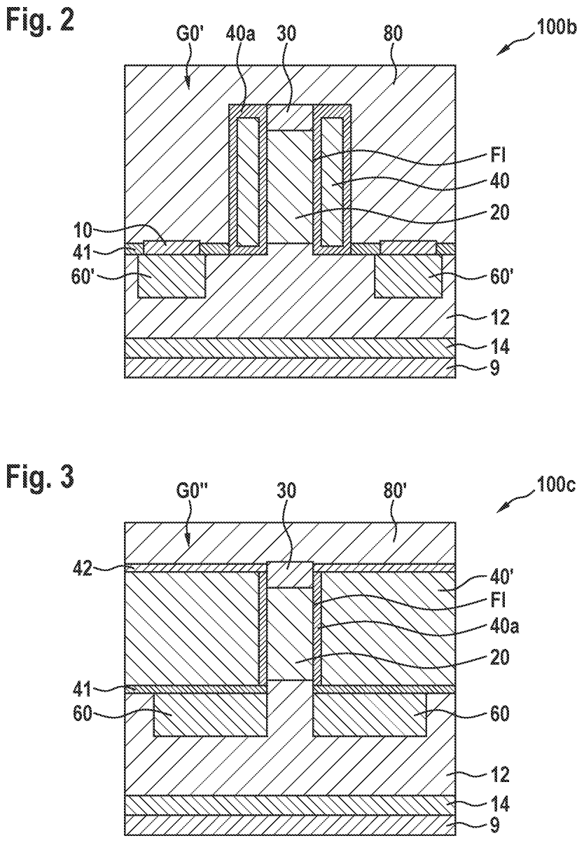

FIG. 2 is a schematic partial cross-sectional view for explaining a vertical field-effect transistor structure according to a second embodiment of the present invention.

In the second embodiment, the highly doped p-regions 60′ of the semiconductor body 100b are spaced further to the left and right from the fin FI. This reduces the shielding effect and forms a smaller space charge zone corresponding to the Schottky junction, and the current has more space. This reduces the so-called JFET or spreading resistance.

Otherwise, the second embodiment is constructed analogously to the first embodiment.

FIG. 3 is a schematic partial cross-sectional view for explaining a vertical field-effect transistor structure according to a third embodiment of the present invention.

While the first and the second embodiment relate to the case of application with a so-called split gate, the third embodiment relates to a stack gate.

The control electrodes 40′ of the semiconductor body 100c completely fill the first trenches G0″ and thus completely cover the highly doped p-regions 60. The source contact metallization 80′ is electrically insulated from the control electrodes 40′ by a further dielectric 42.

In this embodiment, the highly doped p-regions 60 are connected to the source contact metallization 80′ or to the source terminal region 30 by a corresponding electrical connection in the third dimension (not shown).

Otherwise, the third embodiment is constructed analogously to the first embodiment.

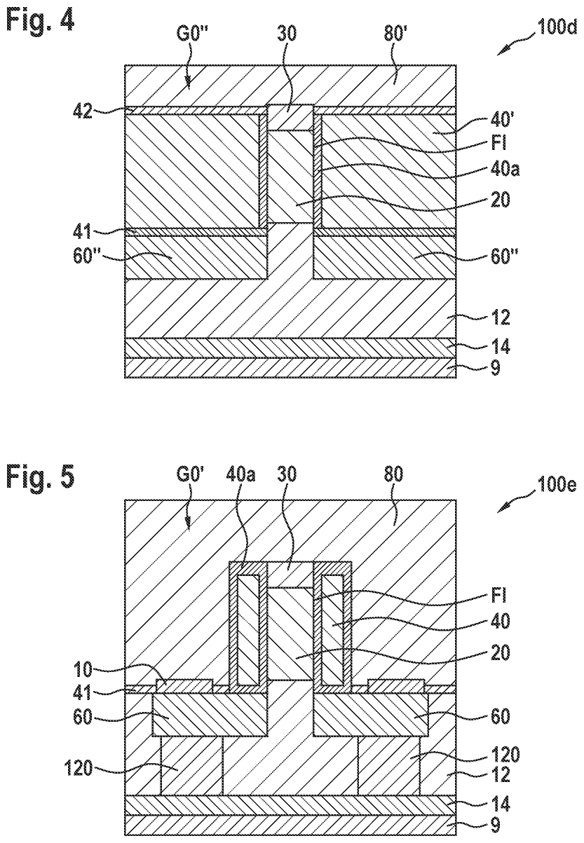

FIG. 4 is a schematic partial cross-sectional view for explaining a vertical field-effect transistor structure according to a fourth embodiment of the present invention.

The fourth embodiment also relates to the case of the stack gate. In contrast to the third embodiment, the highly doped p-regions 60″ of the semiconductor body 100d completely fill the first trenches G0″ below the control electrodes 40′.

Otherwise, the fourth embodiment is constructed analogously to the third embodiment.

FIG. 5 is a schematic partial cross-sectional view for explaining a vertical field-effect transistor structure according to a fifth embodiment of the present invention.

In contrast to the first embodiment, in the fifth embodiment a region 120 of the second conductivity type p is arranged in the semiconductor body 100d in the drift zone 12 between the highly conductive region 60 and the drain terminal region 14, which region of the second conductivity type electrically connects the highly conductive region 60 to the drain terminal region 14.

The regions 120 of the second conductivity type p form so-called superjunction regions. The superjunction regions 120 further reduce the switch-on resistance and at the same time create a shielding effect. In addition, the compromise between short-circuit current, electric field in the oxide, and reverse voltage on the one hand and switch-on resistance on the other is optimized.

In accordance with the method, the superjunction regions 120 can be produced easily by carrying out an implantation step directed into the second trenches G1′ or G1 before filling the second trenches G1′ or widening the second trenches G1 (see FIGS. 1b) and 1c)).

Otherwise, the fifth embodiment is constructed analogously to the first embodiment.

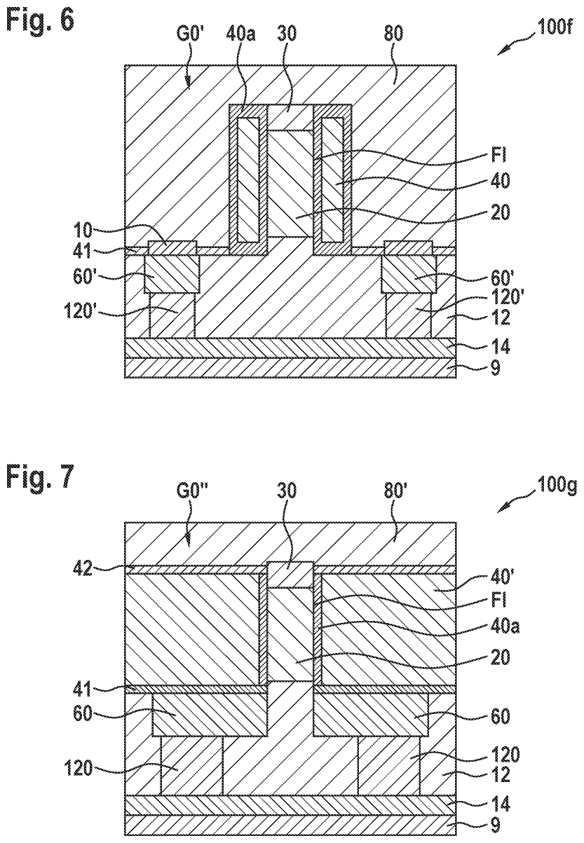

FIG. 6 is a schematic partial cross-sectional view for explaining a vertical field-effect transistor structure according to a sixth embodiment of the present invention.

In contrast to the second embodiment, in the sixth embodiment, a region 120′ of the second conductivity type p is arranged in the semiconductor body 100f in the drift zone 12 between the highly conductive region 60′ and the drain terminal region 14, which region of the second conductivity type electrically connects the highly conductive region 60′ to the drain terminal region 14.

The regions 120′ of the second conductivity type p form the so-called superjunction regions.

Otherwise, the sixth embodiment is constructed analogously to the second embodiment.

FIG. 7 is a schematic partial cross-sectional view for explaining a vertical field-effect transistor structure according to a seventh embodiment of the present invention.

In contrast to the third embodiment, in the seventh embodiment, a region 120′ of the second conductivity type p is arranged in the semiconductor body 100g in the drift zone 12 between the highly conductive region 60 and the drain terminal region 14, which region of the second conductivity type electrically connects the highly conductive region 60 to the drain terminal region 14.

The regions 120 of the second conductivity type p form the so-called superjunction regions.

Otherwise, the seventh embodiment is constructed analogously to the third embodiment.

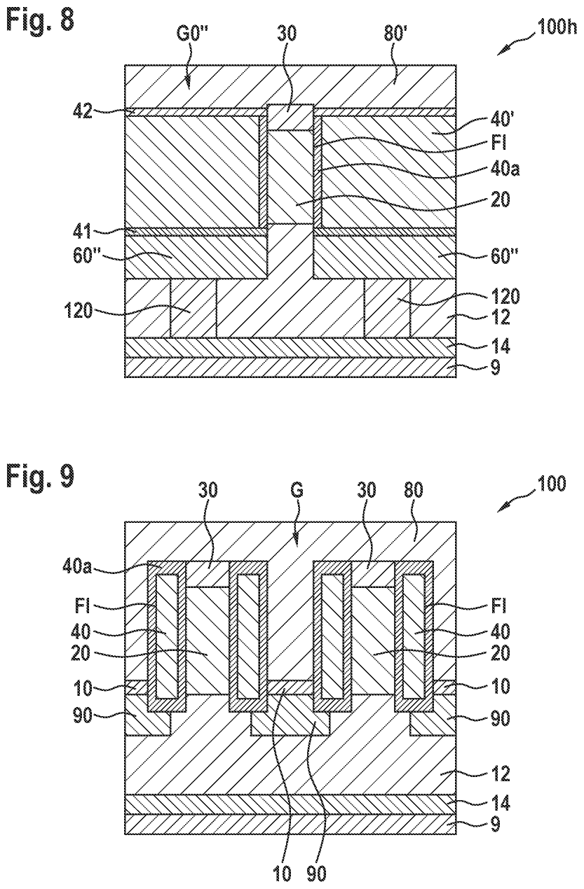

FIG. 8 is a schematic partial cross-sectional view for explaining a vertical field-effect transistor structure according to an eighth embodiment of the present invention. In contrast to the fourth embodiment, in the seventh embodiment, a region 120 of the second conductivity type p is arranged in the semiconductor body 100g in the drift zone 12 between the highly conductive region 60″ and the drain terminal region 14, which region of the second conductivity type electrically connects the highly conductive region 60″ to the drain terminal region 14.

The regions 120 of the second conductivity type p form the so-called superjunction regions.

Otherwise, the eighth embodiment is constructed analogously to the fourth embodiment.

Although the present invention has been described on the basis of preferred exemplary embodiments, it is not limited thereto.

In particular, the mentioned materials and topologies are only exemplary and not limited to the examples explained. The geometries shown are also only exemplary and can be varied as needed.

Although the highly conductive region has been described as a p-region in the above embodiments, it is not limited thereto, but can also be of the n-type or metallic as long as it forms a Schottky junction in the drift zone.

Also, the optional superjunction region does not have to be provided under all highly conductive regions, but can also be provided only under some highly conductive regions, in any order.

What is claimed is:

1. A vertical field-effect transistor structure, comprising:
a semiconductor body having a first terminal zone, a drift zone, and a second terminal zone of a first conductivity type;
a channel zone, arranged between the first terminal zone and the second terminal zone, the channel zone being of the first conductivity type or of a second conductivity type complementary to the first conductivity type;
a plurality of first trenches extending into the semiconductor body, which extend from the second terminal zone into the drift zone and form fins of the channel zone and of the second terminal zone;
a control electrode arranged in the first trenches, the control electrode being arranged adjacent to the channel zone and insulated from the semiconductor body; and
a current path connected between the first terminal zone and the second terminal zone and in parallel with the channel zone, the current path having at least one Schottky junction and is configured to conduct when a reverse voltage between the first terminal zone and the second terminal zone is reached;
wherein the Schottky junction is arranged in the drift zone and is formed between a highly conductive region buried in the drift zone and the drift zone; and
wherein the highly conductive region is electrically connected to the second terminal zone.

2. The vertical field-effect transistor structure according to claim 1, wherein a terminal contact is provided on the highly conductive region and a contact metallization extends into the first trenches, which electrically connects the terminal contact and the second terminal zone.

3. The vertical field-effect transistor structure according to claim 1, wherein the highly conductive region extends up to below the control electrode.

4. The vertical field-effect transistor structure according to claim 1, wherein in the drift zone between the highly conductive region and the first terminal zone there is arranged a region of the second conductivity type which electrically connects the highly conductive region to the first terminal zone.

5. The vertical field-effect transistor structure according to claim 1, wherein the drift region is formed of silicon carbide and the highly conductive region is formed of polysilicon.

6. The vertical field-effect transistor structure according to claim 1, wherein in the drift zone between the highly conductive region and the first terminal zone there is arranged a superjunction region of the second conductivity type which electrically connects the highly conductive region to the first terminal zone.

7. A method for producing a vertical field-effect transistor structure, comprising the following steps:
providing a semiconductor body having a first terminal zone, a drift zone, and a second terminal zone of a first conductivity type;
forming a channel zone, arranged between the first and the second terminal zone, the channel zone being of the first conductivity type or of a second conductivity type complementary to the first conductivity type;
forming a plurality of first trenches extending into the semiconductor body, the first trenches extending from the second terminal zone into the drift zone and form fins of the channel zone and of the second terminal zone;
forming a control electrode arranged in the first trenches, the control electrode being arranged adjacent to the channel zone and insulated from the semiconductor body; and
forming a current path connected between the first and the second terminal zone and in parallel with the channel zone, the current path having at least one Schottky junction and is configured to conduct when a reverse voltage between the first and the second terminal zone is reached;
wherein the Schottky junction is arranged in the drift zone and is formed between a highly conductive region buried in the drift zone and the drift zone; and
wherein the highly conductive region is electrically connected to the second terminal zone.

8. The method for producing a vertical field-effect transistor structure according to claim 7, wherein a terminal contact is formed on the highly conductive region and a contact metallization is formed in the first trenches which electrically connects the terminal contact and the second terminal zone.

9. The method for producing a vertical field-effect transistor structure according to claim 7, wherein the highly conductive region is formed such that it extends up to below the control electrode.

10. The method for producing a vertical field-effect transistor structure according to claim 7, wherein in the drift zone between the highly conductive region and the first terminal zone, a region of the second conductivity type is formed which electrically connects the highly conductive region to the first terminal zone.

11. The method for producing a vertical field-effect transistor structure according to claim 7, wherein the drift region is formed of silicon carbide and the highly conductive region is formed of polysilicon.

12. The method for producing a vertical field-effect transistor structure according to claim 7, wherein the highly conductive region is formed such that second trenches, which are filled with the highly conductive region, are formed in the drift region.

13. The method for producing a vertical field-effect transistor structure according to claim 12, wherein in the drift zone between the highly conductive region and the first terminal zone, a region of the second conductivity type is formed which electrically connects the highly conductive region to the first terminal zone, and wherein the region of the second conductivity type is formed before the filling of the second trenches by an implantation step directed into the second trenches.

14. The method for producing a vertical field-effect transistor structure according to claim 7, wherein in the drift zone between the highly conductive region and the first terminal zone there is formed a superjunction region of the second conductivity type which electrically connects the highly conductive region to the first terminal zone.
